(19) United States
(12) Patent Application Publication
(10) Pub. No.: US 2008/0226939 A1
(43) Pub. Date: Sep. 18, 2008

(54) Protection Film and Organic El Device

(76) Inventor: Hirofumi Kubota, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/586,657

(22) PCT Filed: Jan. 14, 2005
(86) PCT No.: PCT/JP2005/000349

§ 371 Date: Jul. 19, 2006

(30) Foreign Application Priority Data
Jan. 19, 2004 (JP) 2004-010844

(51) Int. Cl. B32B 9/00; C23C 16/30

(52) U.S. Cl. 428/690; 427/579

(57) ABSTRACT

The disclosed is a protection film to be formed on a thin film device formed on a substrate, which is characterized by having a hydrogen content of not less than 30 at %. It is possible to provide a protection film of high reliability and with a thick film thickness as the protection film for the devices such as the organic EL device.

### TECHNICAL FIELD

This technology, for example, relates to a protection film for a device such as an organic electroluminescent device (hereinafter, referred as “organic EL device”), and to a device in which the protection film is formed.

### BACKGROUND ARTS

Recently, organic EL device is remarkable because it is possible to drive by the low voltage comparatively, it has a high luminance and thus it doesn't need a backlight, and it can make a light-weight flat-panel display can be made.

For example, this organic EL device may have a constitution where an organic layer is sandwiched between first and second electrodes which are formed on a substrate so as to face each other.

However, there is a problem that a black macula dark spot is generated in the light emission element when the organic EL device adsorbs moisture and oxygen in the atmosphere, for example. As the generated dark spot is growing up, the lifetime of organic EL device becomes shorter.

In order to protect an organic layer from such moisture and oxygen, conventionally, a surrounding body which is called “sealing can” and which stored a desiccant has been used for sealing the organic EL device. However, when forming such sealing can, the thickness of the display panel has become large. Therefore, some attempts have been made to seal the organic EL device with a thin film.

As such a sealing film, for example, a sealing film which is formed by the plasma CVD method and has a composition of SiOₓC_{y} (x=0.1-1, y=0.1-1), and of which hydrogen content rate is not more than 30 at % is disclosed in the Patent Literature 1.

Further, in the Patent Literature 2, it is proposed to provide a SiₓN_{y}O_{z}:H film which is formed by the plasma CVD method, and has a hydrogen content of not more than 2×10²² atoms/cm², although it is formed as an insulating layer over the luminescent layer of the inorganic EL device. In this literature, it is disclosed that bubbles of hydrogen are generated during the device's operation if the hydrogen content in the film is large.

### Patent Literature 1:

Japan unexamined publication No. 2001-68264 (JP2001-68264A)

Patent literature 2:

Japan unexamined publication No. HEI2-189891 (JP02-189891A (1990))

### DISCLOSURE OF THE INVENTION

### Problem to be Solved by the Invention

When the hydrogen content of the film is reduced as shown in the Patent Literature 1 or 2, the membrane stress will become large, although the film quality improves certainly. Therefore, there are fears that the film cannot be formed as a thick film and that delamination between organic layers or between organic layer and electrode, etc., will happen. Thus, the reliability of the device becomes lacked.

It is known that the plasma CVD method can form a film at a relatively low temperature as compared with, for example, the spattering method, thermal CVD method, and catalyst CVD method, and the plasma CVD film shows a good covering of difference in level (step coverage) for device. However, the amount of hydrogen included in the film prepared by the plasma CVD method is relatively large as compared with such methods. Therefore, it is necessary to improve the film forming temperature to some degree or to raise the RF power when it is intended to form a film of which hydrogen content is not more than 30 at % as disclosed in the above-mentioned Patent Literature 1. On the other hand, since the organic EL materials have a poor heat resistance in general, there is a possibility that the organic EL materials may be deactivated by the temperature when the protection film is formed with such a low hydrogen content, and thus, the preparation of such a film using the plasma CVD method would be accompanied with a technical difficulty.

Therefore, the present technology aims to provide an improved protection film which solves above-mentioned problems in the prior arts, and an organic EL device using such a protection film, and the production method thereof.

### Means for Solving the Problems

A technology which solves the above problems is a protection film for a thin film device formed on a substrate, which is characterized by having a hydrogen content of not less than 30 at %.

Also, the protection film which is one of SiN, SiO, SiON, SiC or SiCN type or diamond like carbon (DLC) is shown.

Another technology which solves the above-mentioned problem is an organic electroluminescent device which comprises at least a first electrode, an organic luminescent layer, and a second electrode formed on a substrate, which is characterized by forming onto the organic electroluminescent device a protection film of which hydrogen content is not less than 30 at %.

Also, the organic electroluminescent device of which the protection film is one of SiN, SiO, SION, SiC or SICN type or diamond like carbon (DLC) is shown.

In addition, a technology which solves the above-mentioned problem is a process for manufacturing an organic electroluminescent device which comprises at least a first electrode, an organic luminescent layer, and an second electrode formed on a substrate, which is characterized by forming onto the organic electroluminescent device a protection film of which hydrogen content is not less than 30 at % through the use of CVD method or spattering method.

Also, the above-mentioned process wherein the CVD method is a plasma CVD method is shown.

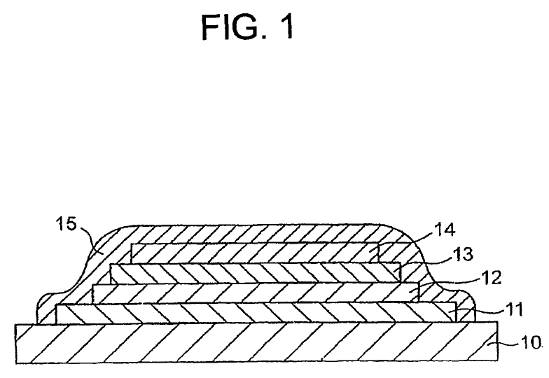

### BRIEF DESCRIPTION OF THE DRAWINGS

[FIG. 1] FIG. 1 is a schematic sectional view of one embodiment of the organic EL device to which the protection film according to the present technology.

### BEST MODE FOR CARRYING OUT THE INVENTION

Now, this technology is described in detail referring to the drawing as follows.

The first disclosed technology is the protection film for a thin film device formed on a substrate, which is characterized by having a hydrogen content of not less than 30 at %.

As the hydrogen content of this protection film, 30-40 at % is more desirable.

Here, the “hydrogen content” shown in this Specification is a value, in the areas up to depth about 500 nm except the outermost oxidized surface area of the sample, and which is measured by the Rutherford's backscatter analysis (RBS)-hydrogen forward scattering analysis (HFS) . Further, the value is the hydrogen amount before the measurement which is presumed from the change in spectrum along elapsed time because hydrogen desorption will progress during the measurement. The purpose of assuming the areas up to depth about 500 nm is to be able to measure the composition distribution only in depth from the surface to about 500 nm in the case of the RBS-HFS measurement.

Conventionally, it was thought that the less the hydrogen of the protection film included in the film, the more it is desirable, considering it from a viewpoint that the device's functional layers and the electrode layers would receive the adverse effect with the gas and others which are generated from the film, and a viewpoint of barrier property of preventing the entry of moisture from the outside.

However, according to our investigation performed, any specific problems were not caused, in the preservation results of the organic EL devices to which a protection film as the protection film to be formed on the organic layer was provided, for example, so as to have a hydrogen content thereof is not less than 30 at %.

Further, the film formation in such a hydrogen content can be performed, for example, by the plasma CVD method, even when the temperature condition for forming the film is set as a considerably low temperature. Therefore, it is possible to apply the film as the protection film for a material having relatively low heat resistance, such as the organic luminescent materials etc. In addition, when the hydrogen content is relatively high as being not less than 30 at %, the membrane stress of the formed protection film will become small, thus, a thick film, for example, of not less than 0.5 μm, preferably, of 1-5 μm can be formed. For instance, even when the lower device constitution to be coated with the film has a considerably large difference in level, the lower device constitution can be covered with the film showing a good difference following. Moreover, it is also possible to bury particles and pinholes. Therefore, even if the concerned protection film is not combined with other films, such as a metallic film, etc., and used as a single film, the protection film per se can perform ample functions. Therefore, it can be preferably used as the protection film to be formed onto the thin film layered article in the organic EL device or other electronic devices.

As a composition of the protection film according to the present technology, it is not especially limited except for the above-mentioned hydrogen content. It may be an inorganic film or an organic film. It is preferable, however, for instance, that the protection film is made of a composition including silicon and at least one element of oxygen, carbon and nitrogen, such as SiN system, SiO system, SiON system, SiC system, and SiCN system, or made of a diamond like carbon (DLC), because it can be expected to form a stable film with an excellent dampproofing, a high reliability, etc.

Such a protection film can be formed by a well-known method including various CVD methods such as thermal CVD, plasma CVD method, and catalyst CVD method, and the sputtering methods.

For example, in the case of the CVD method, the hydrogen content in the film obtained can be regulated to the desirable level by properly adjusting the flow ratios or partial pressures of a raw material gas such as SiH₄,and other gas such as N₂, NH₃, or N₂O, or by properly adjusting RF power or substrate temperature. In case of the sputtering method, the hydrogen content can be regulated to the desirable level by introducing hydrogen source such as hydrogen gas or NH₃ into the reaction system, separately with Si, SiC as the target material.

As the process for manufacturing the protection film, it is desirable to use the plasma CVD method especially among the above-mentioned methods. According to the plasma CVD method, the film of such a high hydrogen content in the present technology can be formed using the film forming temperature condition of not more than 120° C., more preferably, 70-110° C. Therefore, the protection film can be formed so as to cover the material without inflicting damage' to the material, even if the material is one having a low heat resistance such as the organic EL material.

FIG. 1 is a schematic sectional view of one embodiment of the organic EL device according to a second technology to which the protection film according to the first technology is applied.

As for organic EL device shown in FIG. 1, a first electrode 11, an electron hole injection transportation layer 12, an organic luminescent layer 13, and a second electrode 14 is layered on a substrate 10 in that order, and a protection film 15 that has a prescribed hydrogen content rate is formed onto the layered structure so as to cover the entire organic EL device.

Incidentally, as the structure of the organic EL device according to the second technology, it is not limited to the embodiment shown in FIG. 1, but it is possible to adapt any of well-known, various constitutions. For example, a constitution where an organic luminescent layer is provided solely and an electron injection transportation layer is provided between this organic luminescent layer and a second electrode, a constitution where both of an electric hole injection transportation layer and an electron injection transportation layer are provided, or a constitution where an electric hole injection transportation layer and luminescent layer are mixed with each other, are adaptable.

In the organic EL device according to the second technology, since it has the protection film with a high hydrogen content of not less than 30%, the organic luminescent layer can be protected sufficiently from extraneous oxygen and moisture, etc. Thus, it is possible to make the organic EL device with excellent luminescence longevity.

As the thickness of protection film 15 in such an organic EL device, it is desirable to be of not less than 0.5 μm, preferably, 1-5 μm, although it is not especially limited thereto. Since the membrane stress is amply low even when the protection film is manufactured as such a thick film, it is possible to demonstrate an excellent product performance of organic EL device for a long term with stability because a high dampproofing or high gas barrier can be given without causing an interlayer delamination or an abnormal luminescence, etc.

Incidentally, as the materials which each compose a substrate material and respective layers to be stacked in the organic EL device according to this second technology other than the protection layer, there is no especial limitation, and it is possible to use any of well-known materials.

### EXAMPLE

Hereinafter, this invention is concretely described based on the examples.

Organic EL device which had the structure shown in FIG. 1 was manufactured.

As protection film 15, a SiN film of 3 pm in thickness was formed by using SiH₄ and N₂ as a source gas and applying the plasma CVD method under a film formation temperature (substrate surface temperature) condition of 100° C.

The composition of the obtained protection film in the areas up to depth about 500 nm except the oxidized area on the outermost surface was measured by the RBS-HFS method. Since hydrogen desorption was observed during the measurement, the hydrogen amount before the measurement was presumed from the change in spectrum along elapsed time in order to calculate the hydrogen content of the protection film, and the calculated hydrogen content of the protection film was found to be 37 at %.

Organic EL display was manufactured by using the obtained organic EL device, and the obtained organic EL device was subjected to the luminescent experiments under normal temperature condition (22° C.), high temperature condition (100° C.), and high temperature and high humidity condition(60° C., 95% RH). As results, no abnormality such as decline or extinction in the luminance of the EL display was observed during the examination period of 500 hours in each temperature region, and thus the high reliability of the protection film according to the present technology and the high reliability of the organic EL element according to the present technology were demonstrated.

1-6. (canceled)

7. A protection film for a thin film device formed on a substrate, which comprises a hydrogen content of not less than 30 at %.

8. A protection film according to claim 7, wherein the protection film is one of SiN, SiO, SiON, SiC or SiCN type or diamond like carbon (DLC).

9. An organic electroluminescent device which comprises at least a first electrode, an organic luminescent layer, and a second electrode formed on a substrate, wherein the organic electroluminescent device further comprises a protection film which covers the organic electroluminescent device and of which hydrogen content is not less than 30 at %.

10. An organic electroluminescent device according to claim 9, wherein the protection film is one of SiN, SiO, SiON, SiC or SiCN type or diamond like carbon (DLC).

11. A process for manufacturing an organic electroluminescent device which comprises at least a first electrode, an organic luminescent layer, and an second electrode formed on a substrate, which comprises forming a protection film which covers the organic electroluminescent device, wherein hydrogen content of the protection film is not less than 30 at % through the use of CVD method or spattering method.

12. A process according to claim 11, wherein the CVD method is plasma CVD method.
